(19) United States
(12) Patent Application Publication
(10) Pub. No.: US 2026/0206640 A1
(43) Pub. Date: Jul. 16, 2026

(54) METHOD FOR EUTECTIC SEALING OF TWO SUBSTRATES

(71) Applicant: COMMISSARIAT A L'ENERGIE ATOMIQUE ET AUX ENERGIES ALTERNATIVES, Paris (FR)

(72) Inventors: Audrey BERTHELOT, Grenoble Cedex 09 (FR); Frank FOURNEL, Grenoble Cedex 09 (FR); Pierre PERREAU, Grenoble Cedex 09 (FR); Grégory ENYEDI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/137,933

(22) PCT Filed: Dec. 11, 2023
(86) PCT No.: PCT/FR2023/051976

§ 371 Date: Jun. 11, 2025

(30) Foreign Application Priority Data
Dec. 19, 2022 (FR) FR2213770

(51) Int. Cl. H10W 76/63; H10W 76/01

(52) U.S. Cl. CPC H10W 76/63; H10W 76/01

(57) ABSTRACT

A method for eutectic sealing of two substrates. The first substrate is covered by a first bead comprising a first element, and the second substrate is covered by a second bead comprising a second element. The first bead and the second bead are placed in contact and heated to form a eutectic phase alloying the first element and the second element. Here, a sealing bead containing a eutectic alloy is formed, and the first substrate is sealed to the second substrate with the formation of the eutectic phase being accompanied by the formation of run-outs. At least one of the first substrate and the second substrate is covered locally by a wettability layer, and during the contacting and heating, the run-outs of eutectic alloy form on the wettability layer.

### TECHNICAL FIELD

The present invention relates to the general field of microelectronics and, more particularly, that of the encapsulation (or packaging) of a microelectronic device such as a microsystem of the MEMS (‘Micro-Electro-Mechanical Systems’), NEMS (‘Nano-Electro-Mechanical Systems’), MOEMS (‘Micro-Opto-Electro-Mechanical Systems’), or NOEMS (‘Nano-Opto-Electro-Mechanical Systems’) type, consisting in encapsulating, or enclosing, this device in a sealed cavity, the atmosphere of which is controlled.

The invention relates to a method for hermetically sealing two substrates.

The invention also relates to a device obtained by such a method.

The invention has uses in many industrial fields, for example in the field of motor vehicles, mobile phones or for video game consoles.

The invention is of particular interest since it allows to hermetically seal the substrates with a eutectic alloy while avoiding the risks of short circuit or mechanical blockage of the mobile structures.

### PRIOR ART

Microelectronic devices of the MEMS, NEMS, MOEMS or NOEMS type are sensors or actuators having a nanometric or micrometric size. They are manufactured via microelectronics methods.

The encapsulation of these microelectronic devices allows, on the one hand, to protect them against external elements (humidity, particulate pollution, reactive elements such as oxygen) and, on the other hand, to control the atmosphere (pressure, composition of the encapsulated gas, etc.) prevailing in the cavity in which these devices are encapsulated. The encapsulation pressure prevailing in the cavity is variable according to the intended use and is, typically, between 10⁻³ mbar and 1 bar.

Various types of sealing can be implemented for this encapsulation: thermo-compression, eutectic sealing, anodic sealing, etc.

At present, eutectic sealing seems to be the most promising.

Typically, as shown in FIGS. 1A and 1B, in the eutectic sealing method, the components of the alloy are deposited separately on the faces of the substrates 11, 12 to be assembled. On the first substrate 11, a first bead 21 of material is formed. On the second substrate 12, a second bead 22 of material is formed (FIG. 1A).

During the sealing, the two substrates 11, 12 are placed into close contact and a temperature is applied to the entire system. Melting occurs at the eutectic temperature if the relative composition of the two materials corresponds to the eutectic concentration. In the liquid phase, a homogeneous liquid composed of the two materials is present between the two faces. Then the solidification of the braze will lead to the formation of a material composed of a phase separation of the materials used to carry out the eutectic melting within the limit of their respective solubility. This material is then called eutectic material even if it is not formed by a single phase. This eutectic material is then between the two substrates 11, 12 and allows the mechanical closure of the interface to form the final assembly.

The eutectic material thus passes through a liquid state before solidifying and forming a hermetic bead 23 around the chips to be encapsulated (FIG. 1B).

However, the passage in liquid phase can be accompanied by flow of eutectic material out of the zone of the sealing bead (FIG. 2). These run-outs 23′, which solidify, can cause possible mechanical blockages of the mobile structures, and/or generate short circuits between various zones of the device.

It is therefore necessary to control the leakage of the liquid braze.

For example, in the thesis by V. Lumineau (2018 ‘Study of the bonding of MEMS by Al—Ge eutectic alloy’), it was proposed to form stops adjacent to the beads. These stops limit the moving closer together of the two plates to be assembled and thus the crushing of the Al—Ge bilayer. However, for this solution to work, it is necessary to place solid stops on each side of the bead at a certain distance. However, this solution cannot be applied to all devices because of the constraints of compactness of the various structures, for example.

### DISCLOSURE OF THE INVENTION

One goal of the present invention is to propose a eutectic sealing method overcoming the disadvantages of the prior art and allowing to hermetically seal two substrates, while avoiding the phenomena of short circuits and mechanical blockage.

For this, the present invention proposes a method for eutectic sealing of two substrates comprising the following steps:
a) providing a first substrate having a first face covered by a first bead made of a first material, and optionally by one or more microelectronic devices, the first material comprising a first element,
b) providing a second substrate having a first face covered by a second bead made of a second material, and optionally by one or more microelectronic devices, the second material comprising a second element, capable of forming a eutectic alloy with the first element,
c) placing the first bead and the second bead in contact, and carrying out a heat treatment to form a eutectic phase alloying the first element of the first bead and the second element of the second bead, whereby a sealing bead containing the eutectic alloy is formed and the first substrate is sealed to the second substrate, the formation of the eutectic phase being accompanied by the formation of run-outs of eutectic alloy.

It is also possible to use a first bead comprising the first material and the second material, for example in the form of a multilayer, and/or a second bead comprising the first material and the second material, for example in the form of a multilayer.

It is thus possible to form a symmetrical configuration.

It is also possible to form an asymmetric configuration, for example, by having a first bead comprising the first material and a second bead comprising the second material on which a part of the first material has been deposited. In this case, the first material on the first face of the first substrate is thinner to keep the eutectic concentration before the melting.

According to another alternative embodiment, the asymmetric configuration is obtained by having a second bead comprising the second material and a first bead comprising the first material on which a part of the second material has been deposited. In this case, the second material on the first face of the second substrate is thinner to keep the eutectic concentration before the melting.

It is possible to modify the distribution of the materials on just one of the two faces or on both faces.

Advantageously, a configuration leading to the formation of an atomic flow through the bonding interface, that is to say an asymmetric configuration, is chosen.

In this method, at least one of the first substrate and the second substrate is covered locally by a wettability layer, the contact angle of a drop of eutectic alloy on the wettability layer being smaller by at least 20° and preferably by at least 40°, on the one hand, than the contact angle of eutectic alloy on the first face of the first substrate and, on the other hand, than the contact angle of eutectic alloy on the first face of the second substrate, whereby during step c), the run-outs of eutectic alloy preferably go onto the wettability layer.

The invention fundamentally differs from the prior art by the implementation of at least one zone of preferential wettability of the eutectic alloy opposite the substrate. The eutectic material formed during step c) has better wettability on the wettability layer than on the faces of the first and second substrates.

Thus, instead of placing a ‘physical’ barrier (like the stops in the prior art), a so-called ‘energetic’ barrier with a face with high surface energy for the liquid metal and a wetting zone with lower surface energy is used. The liquid metal wets this wetting zone as if it were falling into a potential well. By cleverly integrating a preferential wettability layer, the run-outs of eutectic material are guided and maintained in a zone ‘not risky’ for the functionality of the chip.

For example, in the case of the eutectic alloy Al—Ge, the wettability of this alloy is better on a metal face than on a face of the dielectric type. The positioning of a metallic wettability layer in contact with or near the location of the sealing bead allows to contain the run-outs in the case of a substrate having a face made of a dielectric material.

In particular, a substrate is chosen for which the contact angle of a drop of eutectic alloy is greater than or equal to 90°, preferably greater than or equal to 100°.

For example, a wettability layer for which the contact angle of a drop of eutectic alloy is less than or equal to 70°, preferably less than or equal to 60° and even more preferably less than or equal to 40° is chosen.

With this sealing method, the molten metal alloy adheres onto the faces of the substrates to be assembled and the run-outs are contained at the wettability layer. The cavity thus sealed is hermetic and the assembly has good mechanical strength.

Advantageously, the wettability layer (also called wetting layer) is a metal layer. Preferably, the metal layer is made of a metal chosen from W, Ti, Al, Au and Cu.

According to another advantageous alternative, the wettability layer is a layer of metal nitride, such as TiN, WN, AlN.

According to another advantageous alternative, the wettability layer is a layer of semiconductor such as Si, Ge, SiC, AsGa, InP.

Advantageously, the first face of the first substrate is made of a dielectric material, preferably SiO₂ or Si₃N₄, a semiconductor material or metal nitride such as TiN, WN, AlN (the wettability layer is then preferably made of metal) and/or the first face of the second substrate is made of a dielectric material, preferably SiO₂ or Si₃N₄, or a semiconductor material or metal nitride such as TiN, WN, AlN (the wetting layer is then preferably made of metal).

Advantageously, the eutectic alloy is chosen from Al—Ge, Au—In, Au—Sn, Au—Si, Bi—Sn and Au—Ge.

Advantageously, the first material is chosen from AlSi or AlCu for the eutectic alloy AlGe, Au for the eutectic alloy Au—In, Au—Sn, Au—Si or Au—Ge, Bi for the eutectic alloy Bi—Sn and/or the second material is chosen from Ge for the eutectic alloy Al—Ge or Au—Ge, Sn for the eutectic alloy Au—Sn or Bi—Sn, Si for the eutectic alloy Au—Si, In for the eutectic alloy Au—In.

The first element has a volume V1 and the second element has a volume V2. The volumes V1 and V2 are chosen so as to form a eutectic alloy with the relative concentrations given by V1 and V2. The relative volumes and compositions of the two elements are chosen so as to correspond to the eutectic concentration.

According to a first advantageous embodiment, the first bead is disposed on the first wettability layer, the wettability layer protruding either on one side of the first bead or on either side of the first bead and/or the second bead is disposed on the second wettability layer, the wettability layer protruding either on one side of the second bead or on either side of the second bead.

According to a second advantageous embodiment, the wettability layer(s) is/are offset with respect to the first bead and/or with respect to the second bead, the wettability layer(s) being optionally connected to the first bead and/or to the second bead by cross-members. The cross-members are advantageously made of the same material as the wettability layer.

The invention also relates to a device thus obtained. The device comprises a first substrate and a second substrate sealed to one other by a sealing bead containing a eutectic alloy, at least one of the first substrate and the second substrate being covered locally by a wettability layer, the contact angle of a drop of eutectic alloy on the wettability layer being smaller, on the one hand, than the contact angle of eutectic alloy on the first face of the first substrate and, on the other hand, that the contact angle of eutectic alloy on the first face of the second substrate, the run-outs of the eutectic alloy being trapped on the wettability layer.

Advantageously, the wettability layer is a metal layer, preferably chosen from W, Ti, Al, Au and Cu, the first face of the first substrate is made of a dielectric material, preferably SiO₂, or a semiconductor material and/or the first face of the second substrate is made of a dielectric material, preferably SiO₂, or a semiconductor material.

Advantageously, the eutectic alloy is chosen from Al—Ge, Au—In, Au—Sn, Au—Si, Bi—Sn and Au—Ge.

According to a first advantageous embodiment, the sealing bead is disposed on the wettability layer, the wettability layer protruding either on one side of the sealing bead or on either side of the sealing bead.

According to a second advantageous embodiment, the wettability layer is offset locally with respect to the sealing bead, the wettability layer being connected to the sealing bead by cross-members. Advantageously, the cross-members are made of the same material as the wettability layer.

Other features and advantages of the invention will appear from the following additional description.

It goes without saying that this additional description is given solely as an illustration of the object of the invention and should in no case be interpreted as a limitation of this object.

### BRIEF DESCRIPTION OF THE DRAWINGS

The present invention will be better understood upon reading the description of exemplary embodiments given for purely informational and in no way limiting purposes while referring to the appended drawings in which:

FIGS. 1A and 1B, previously described, show, schematically, various steps of a eutectic sealing method according to the prior art.

FIG. 2, previously described, is an image showing run-outs of a eutectic alloy resulting from a method of the prior art, as shown in FIGS. 1A and 1B.

FIGS. 3A and 3B show, schematically, various steps of a eutectic sealing method according to a specific embodiment of the invention.

FIGS. 4A and 4B show, schematically, various steps of a eutectic sealing method according to another specific embodiment of the invention.

FIGS. 5A and 5B show, schematically, various steps of a eutectic sealing method according to another specific embodiment of the invention.

FIGS. 6A and 6B show, schematically, various steps of a eutectic sealing method according to another specific embodiment of the invention.

FIG. 7 shows, schematically and in a top view, a bead disposed on a wettability layer, according to a specific embodiment of the invention.

FIGS. 8A and 8B show, schematically, various steps of a eutectic sealing method according to another specific embodiment of the invention; the wettability layer and the bead shown in a cross-section in FIG. 8A correspond to those of FIG. 9, according to the cross-section defined by the dashed line.

FIG. 9 shows, schematically and in a top view, a bead of material disposed on a wettability layer, according to a specific embodiment of the invention.

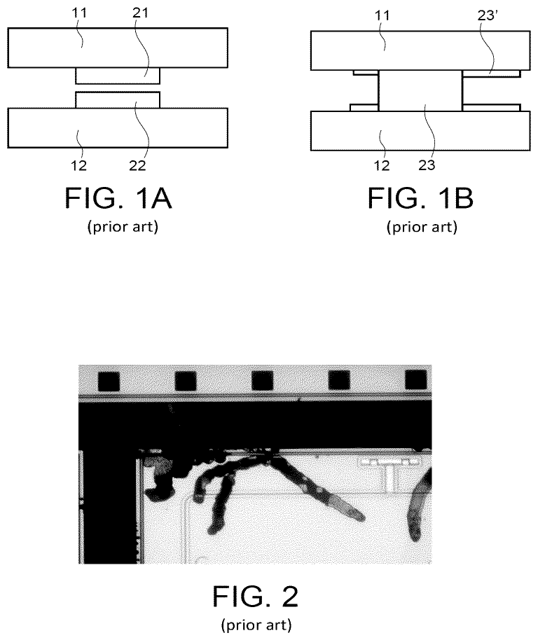

The various parts shown in the drawings are not necessarily on a uniform scale, to make the drawings more legible.

The various possibilities (alternatives and embodiments) should be understood as not being exclusive of each other and can be combined together.

Furthermore, in the description below, terms that depend on the orientation, such as ‘top’, ‘bottom’, etc., of a structure apply while considering that the structure is oriented in the manner illustrated in the drawings.

### DETAILED DISCLOSURE OF SPECIFIC EMBODIMENTS

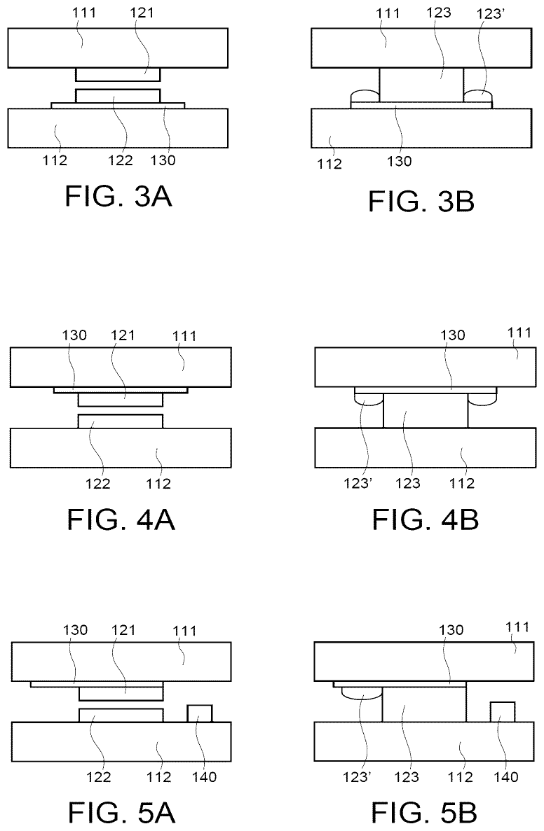

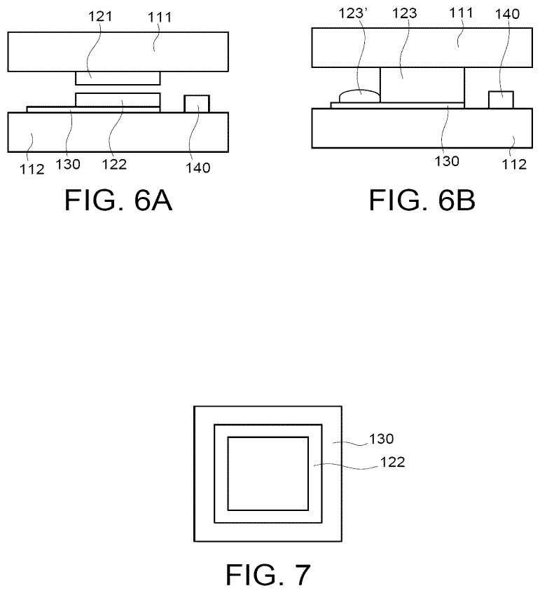

The method for eutectic sealing of two substrates will now be described in more detail while referring to the appended FIGS. 3A and 3B, 4A and 4B, 5A and 5B, 6A and 6B, 7, 8A and 8B, 9.

The method for eutectic sealing of two substrates comprises the following steps:
a) providing a first substrate 111 having a first face covered by a first bead 121 made of a first material, and optionally by one or more microelectronic devices 140, the first material comprising a first element,
b) providing a second substrate 112 having a first face covered by a second bead 122 made of a second material, and optionally by one or more microelectronic devices 140, the second material comprising a second element, capable of forming a eutectic alloy with the first element,
c) placing the first bead 121 and the second bead 122 in contact,
d) carrying out a heat treatment to form a eutectic phase alloying the first element provided by the first bead and the second element provided by the second bead, whereby a sealing bead 123 containing the eutectic alloy is formed and the first substrate 111 is sealed to the second substrate 112 with the sealing bead 123.

The sealing bead 123 obtained and the two substrates 121, 122 define a hermetic cavity in which, advantageously, one or more microelectronic devices 140 are disposed. The encapsulation pressure prevailing in the cavity is variable according to the intended use and is typically between 10⁻³ mbar and 1 bar (or between 0.1 Pa and 100,000 Pa).

In this method, at least one of the first substrate 111 provided in step a) and the second substrate 112 provided in step b) is covered locally by a wettability layer 130, whereby during step c), the run-outs 123′ of the eutectic alloy form on the wettability layer 130 and are contained at least partially, and preferably, totally at this layer 130.

Each substrate 111, 112 provided in step a) and in step b) comprises two main faces parallel to one another. The first face of the first substrate 111 is intended to be placed facing the first face of the second substrate 112.

The substrates 111 and 112 can consist mostly of the same material or the substrates 111 and 112 can consist of different materials. These materials can be chosen from Si, Ge, InP, AsGa, Al₂O₃, SiC, GaN, LNO, LTO.

The first substrate 111 and/or the second substrate 112 can comprise a support substrate covered by a thin layer. The thin layer thus forms the first face of the first substrate or the first face of the second substrate.

The first face of the first substrate 111 and/or the first face of the second substrate 112 can be made of an SiO₂, Si₃N₄ dielectric material or a metal nitride such as TiN, WN or AlN.

Preferably, the first face of the first substrate 111 and/or the first face of the second substrate 112 are made of oxide, for example SiO₂. This can be a layer of native oxide, a layer of thermal oxide or a deposited layer of oxide.

Thus, it is possible to have a first substrate 111 comprising a support substrate made of Si covered by a thin layer of SiO₂. The same applies to the second substrate 112.

The first face of the first substrate 111 and/or the first face of the second substrate 112 can be of an identical nature or of different natures.

The first substrate and the second substrate each have, for example, a thickness of between 300 μm and 1,000 μm.

One or more microelectronic devices 140 can be disposed on the first face of the first substrate 111 and/or on the first face of the second substrate 112. The microelectronic devices of the first substrate 111 can be identical or different from those present on the second substrate 112.

Microelectronic device means a microelectronic component, for example such as a microsystem of the MEMS (‘Micro-Electro-Mechanical Systems’), NEMS (‘Nano-Electro-Mechanical Systems’), MOEMS (‘Micro-Opto-Electro-Mechanical Systems’), or NOEMS (‘Nano-Opto-Electro-Mechanical Systems’) type. For example, this can be an infrared microdetector, transistor, microbattery, capacitor, supra-capacitor, photovoltaic component, accelerometer, pressure sensor, microphone, antenna, rate gyro or gyroscope, any other device deemed necessary for achieving the final object.

The first material of the first bead 121 can be chosen from AlSi or AlCu for the eutectic alloy AlGe, Au for the eutectic alloy Au—In, Au—Sn, Au—Si or Au—Ge, Bi for the eutectic alloy Bi—Sn.

The second material of the second bead 122 can be chosen from Ge for the eutectic alloy Al—Ge or Au—Ge, Sn for the eutectic alloy Au—Sn or Bi—Sn, Si for the eutectic alloy Au—Si, In for the eutectic alloy Au—In.

Preferably, the first material comprises aluminium and the second material comprises germanium to form the eutectic alloy AlGe.

The first material can consist of the first element and/or the second material can consist of the second element.

For example, the first material can be aluminium and the second material germanium.

It is also possible as described above to have symmetrical or asymmetrical configurations.

It is possible, for example, to have a first bead in the form of a multilayer comprising a layer of aluminium covered by a thin layer of germanium (for example the thin layer has a thickness of 10 nm) and a second bead consisting of germanium.

It is possible to deposit an additional layer on the first face of the first substrate and the first material and/or on the first face of the second substrate and the second material. For example, it is possible to deposit a thin layer of Ge on aluminium itself deposited on a layer of SiO₂. The wetting layer can be removed later. For example, it is possible to deposit a 10 nm layer of Ge on the aluminium. The presence of the layer of Ge promotes the reaction between the aluminium and the germanium by facilitating the onset of the reaction on the aluminium despite the presence of a layer of aluminium oxide that can form. When the entire surface of the substrate is covered by this layer of Ge, the devices are formed on this layer. It is also possible to remove a part of the layer of Ge and optionally a part of the layer of aluminium if necessary.

This layer is in general deposited just before the bonding step.

Preferably, the wettability layer 130 is a metal layer. Advantageously, the wettability layer is made of W, Ti, Al, Au or Cu.

According to a very advantageous embodiment, the wettability layer 130 is a metal layer, the first face of the first substrate 111 is made of a dielectric, semiconductor material or a metal nitride and the first face of the second substrate 112 is made of a dielectric, semiconductor material or a metal nitride.

The wettability of the eutectic is better on the wettability layer 130 than on the first face of the first substrate 111 or on the first face of the second substrate 112. Thus, the eutectic alloy remains on the wettability layer 130 rather than flowing onto the substrates.

‘The wettability of the eutectic is better’ means that the contact angle of the drop of eutectic on the first face of the first substrate 111 or on the first face of the second substrate 112 is at least 20° and preferably at least 40° greater than the contact angle of the drop of eutectic on the wettability layer 130.

For example, the contact angle of the drop of AlGe on a face made of SiO₂ is greater than 110° (thesis V. Lumineau). The silicon oxide is not therefore wetted by the eutectic alloy Al—Ge. Thus, a wettability layer 130 for which the contact angle of the drop of AlGe on this layer is less than or equal to 90°, preferably less than or equal to 70° is advantageously chosen.

In order to determine the contact angle of the drop of the eutectic alloy, the method used is, for example, that described in the thesis by V. Lumineau. The measurement of the contact angle is that of the drop placed: the shape of a drop of the eutectic alloy formed on a flat face for a temperature greater than its melting temperature is observed. For this, the alloy is placed in a crucible made of alumina which ends with a capillary having a diameter of 0.6 mm. After the melting has been carried out and the experimental temperature has been reached, a piston allows to form a drop at the end of the capillary. The crucible is then lowered towards the solid face to be studied and the drop is deposited. The observations are carried out in situ, at temperature, using a camera (25 images/s) and through a window. The video recording of the spreading of the drop then allows the measurement and the calculation of the intrinsic parameters of the drops via the software Drop Shape Analysis. A pumping system allows to obtain a high vacuum that can reach 5.10⁻⁷ mbar (or 5.10⁻⁵ Pa).

The wettability layer 130 can be disposed according to several configurations.

The wettability layer 130 can be disposed between the first substrate 111 and the first bead 121 (FIGS. 4A and 4B), and/or between the second substrate 112 and the second bead 122 (FIGS. 3A and 3B).

The wettability layer 130 protrudes from the bead 121, 122 so as to have a free face to contain the run-out 123′. The wettability layer 130 can protrude on either side of the bead 121, 122. Alternatively, it can protrude only on one side of the bead 121, 122. The overflow zone of the wettability layer 130 can be between several tens of nanometers to several hundred micrometres.

The wettability layer 130 can protrude on either side of the bead 121, 122 which covers it (FIGS. 3A and 3B, 4A and 4B).

Alternatively, the wettability layer can protrude only on one side of the bead (FIGS. 5A and 5B, 6A and 6B, 7). Advantageously, the wettability layer 130 protrudes only outside of the cavity formed by the sealing bead 123 and the two substrates to guide the eutectic run-outs 123′ out of the cavity containing the chip microelectronic device(s) and preserve them.

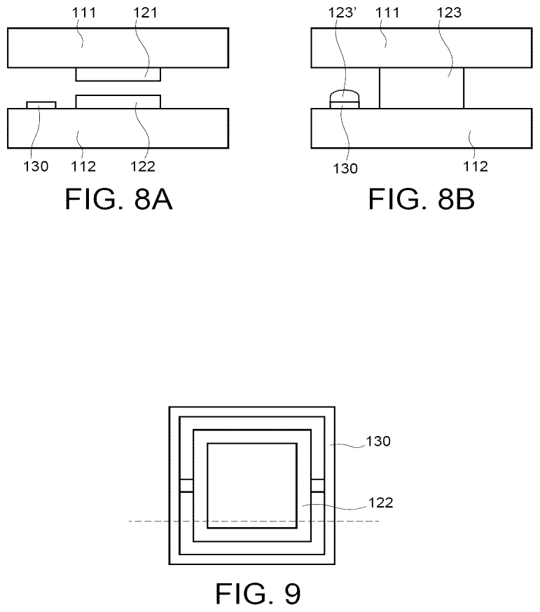

According to another alternative embodiment, the wettability layer 130 can be disposed next to the bead 121, 122 (FIGS. 8A and 8B, 9). It can be in contact with the bead 121, 122 or remote from the bead 121, 122 (i.e. the wettability layer does not touch the bead). For example, the wettability layer 130 forms a belt around the bead. Cross-members (or ‘bridges’) can facilitate the evacuation of the run-outs towards the wettability layer. The cross-members can be made of a material identical or different from that of the wettability layer. Preferably, the wettability layer 130 is located only outside of the sealing bead (i.e. outside of the cavity) and is separated from the sealing bead.

A single wettability layer 130 has been described. It is also possible to have a wettability layer on each substrate 111, 112.

Alternatively, the first substrate 111 and the second substrate 112 are each covered locally by a wettability layer 130, whereby during step c), the run-outs 123′ of the eutectic alloy form on the wettability layers 130 and are contained at least partially and preferably totally at these layers.

The use of two wettability layers allows to better confine the eutectic material and thus stabilise it. Such a configuration can also allow to reduce the dimensions of these layers with respect to a single wettability layer, which is particularly advantageous for miniaturising the devices.

The two layers can be disposed on each substrate identically or differently.

The size of the wettability layer 130 is determined according to the size of the beads. Its size is chosen so as to be able to contain the run-outs.

During step c), the two beads 121, 122, or even the two substrates 111, 112, are placed in close contact with one another then the heat treatment is carried out. The treatment can be carried out under a controlled atmosphere (vacuum, inert atmosphere) and/or with a mechanical pressure to contact the entire face. For example, a force greater than or equal to 2 kN or 10 kN or even 30 kN can be applied.

The temperature is chosen according to the eutectic alloy. The temperature is chosen so as to reach, or even exceed, the melting temperature of the eutectic alloy, to form a braze containing the eutectic alloy between the substrates 111, 112 to be assembled. Preferably, the temperature applied is lower than the melting temperature of the first bead 121 and the melting temperature of the second bead 122. For example, to produce the eutectic alloy Al—Ge, a temperature greater than 425° C. is applied (melting temperature of the eutectic alloy).

The sealing bead 123 is made of a eutectic alloy comprising two elements, one coming from the first element of the first bead and the other coming from the second element of the second bead. This alloy is also called braze.

The formation of the bead 123 made of eutectic alloy ensures the high mechanical strength of the sealing.

The sealing bead 123 has, for example, a width of between 30 μm and 200 μm. The width is chosen so as to be large enough to allow good hermeticity while being small enough to allow miniaturisation.

The sum of the thicknesses of the first and second materials is in general between 100 nm and 10 μm. Preferably it is 1 μm.

The use of a wetting layer can be combined with the use of a mechanical stop as described in the prior art.

The method described above allows to produce assemblies, the thickness of which is less than 10 μm. In addition, the sealing has little defectivity of the hole type at the interfaces relative to thermo-compression, which is of interest for the assemblies requiring a controlled atmosphere.

1. A method for eutectic sealing of two substrates, the method comprising:
a) providing a first substrate having a first face covered by a first bead made of a first material, and optionally by one or more microelectronic devices the first material comprising a first element;
b) providing a second substrate having a first face covered by a second bead made of a second material, and optionally by one or more microelectronic devices, the second material comprising a second element, capable of forming a eutectic alloy with the first element;
c) placing the first bead and the second bead in contact; and
carrying out a heat treatment to form a eutectic phase alloying the first element of the first bead and the second element of the second bead, whereby a sealing bead comprising the eutectic alloy is formed and the first substrate is sealed to the second substrate, the formation of the eutectic phase being accompanied by the formation of run-outs of eutectic alloy,
wherein at least one of the first substrate and the second substrate is covered locally by a wettability layer, the contact angle of a drop of eutectic alloy on the wettability layer being smaller by at least 20°, on the one hand, than the contact angle of eutectic alloy on the first face of the first substrate and, on the other hand, than the contact angle of eutectic alloy on the first face of the second substrate, whereby during step c), the run-outs of eutectic alloy form on the wettability layer.

2. The method of claim 1, wherein the first bead comprises the first material and the second material, and/or
the second bead comprises the first material and the second material.

3. The method of claim 1, wherein the wettability layer is a metal layer or a layer of metal nitride.

4. The method of claim 1, wherein the first face of the first substrate is made of a dielectric material, Si₃N₄, of a semiconductor material, or a metal nitride, and/or
wherein the first face of the second substrate is made of a dielectric material, Si₃N₄, a semiconductor material, or a metal nitride.

5. The method of claim 1, wherein the eutectic alloy is chosen from Al—Ge, Au—In, Au—Sn, Au—Si, Bi—Sn, and Au—Ge.

6. The method of claim 1, wherein the first material is selected from AlSi or AlCu for the eutectic alloy AlGe, and Au for the eutectic alloy Au—In, Au—Sn, or Au—Si, and/or
wherein the second material is selected from Ge for the eutectic alloy Al—Ge, Sn for the eutectic alloy Au—Sn or Bi—Sn, and Si for the eutectic alloy Au—Si.

7. The method of claim 1, wherein the first bead is disposed on the wettability layer, the wettability layer protruding either on one side of the first bead or on either side of the first bead, or
wherein the second bead is disposed on the wettability layer, the wettability layer protruding either on one side of the second bead or on either side of the second bead.

8. The method of claim 1, wherein the wettability layer is offset with respect to the first bead or with respect to the second bead, the wettability layer being connected to the first bead or to the second bead by cross-members.

9. A device, comprising:
a first substrate; and
a second substrate,
wherein the first substrate is sealed to the second substrate by a sealing bead comprising a eutectic alloy,
at least one of the first substrate and the second substrate is covered locally by a wettability layer,
the contact angle of a drop of eutectic alloy on the wettability layer is smaller, on the one hand, than the contact angle of eutectic alloy on the first face of the first substrate and, on the other hand, than the contact angle of eutectic alloy on the first face of the second substrate, and
run-outs of the eutectic alloy are disposed on the wettability layer.

10. The device of claim 9, wherein the wettability layer is a metal layer or a layer made of metal nitride, and
wherein the first face of the first substrate is made of a dielectric material, Si₃N₄, a semiconductor material, or a metal nitride, and/or
wherein the first face of the second substrate is made of a dielectric material, Si₃N₄, a semiconductor material, a metal nitride.

11. The device of claim 9, wherein the eutectic alloy is chosen from Al—Ge, Au—In, Au—Sn, Au—Si, Bi—Sn, and Au—Ge.

12. The device of claim 9, wherein the sealing bead is disposed on the wettability layer, the wettability layer protruding either on one side of the sealing bead or on either side of the sealing bead.

13. The device of claim 9, wherein the wettability layer is locally offset with respect to the sealing bead, the wettability layer being connected to the sealing bead by cross-members.
